(19) United States
(12) Patent Application Publication
(10) Pub. No.: US 2013/0062626 A1
(43) Pub. Date: Mar. 14, 2013

(54) POWER SEMICONDUCTOR MODULE

(71) Applicants: Kazuto TAKAO, Ibaraki (JP); Takashi Shinohe, Kanagawa (JP)

(72) Inventors: Kazuto TAKAO, Ibaraki (JP); Takashi Shinohe, Kanagawa (JP)

(73) Assignee: KABUSHIKI KAISHA TOSHIBA, TOKYO (JP)

(21) Appl. No.: 13/409,492

(22) Filed: Mar. 1, 2012

(30) Foreign Application Priority Data
Sep. 8, 2011 (JP) 2011-195670

(51) Int. Cl. H01L 29/16; H01L 29/20

(52) U.S. Cl. 257/77; 257/76; 257/E29.082; 257/E29.089

(57) ABSTRACT

Disclosed is a power semiconductor module which includes a unipolar type switching device using a wide bandgap semiconductor (wide bandgap semiconductor switching device) and an insulated gate bipolar transistor using a silicon semiconductor (Si-IGBT) connected in parallel, in which a chip area of the wide bandgap semiconductor switching device is smaller than that of the Si-IGBT.

### CROSS-REFERENCE TO RELATED APPLICATION

This application is based upon and claims the benefit of priority from the prior Japanese Patent application No. JP2011-195670, filed on Sep. 8, 2011; the entire contents of which are incorporated herein by reference.

### FIELD

Embodiments described herein relate generally to a power semiconductor module.

### BACKGROUND

A power converter such as an inverter is employed in an electric vehicle, a photovoltaic power conditioner system, and the like. In order to improve the entire system efficiency, it is desirable to reduce power loss in the power converter.

Since the power loss in the power semiconductor module comes up to about 50% of the power loss in the power converter, it is important to reduce the loss in the power semiconductor module.

In the related art, an element made of silicon (Si) is widely employed as a switching device of the power semiconductor module. In particular, an insulated gate bipolar transistor (Si-IGBT) is widely employed as a switching device having a withstanding voltage of 600 V or higher.

In recent years, as a switching device is less likely to suffer power loss than the Si switching device, a metal oxide semiconductor field effect transistor (MOSFET), a junction field effect transistor (JFET), a high electron mobility transistor (HEMT), and the like using a wide bandgap semiconductor such as SiC, GaN, and diamond have been focused on in the art.

### BRIEF DESCRIPTION OF THE DRAWINGS

FIG. 1 is a graph illustrating the comparison of a forward current-voltage characteristic per unit area between a SiC-MOSFET and a Si-IGBT;

FIG. 2 is a graph illustrating the comparison of a forward current-voltage characteristic when the chip area of the SiC-MOSFET is set to be ½ or ⅓ times that of the Si-IGBT;

FIG. 3 is a diagram illustrating an equivalent circuit of the power semiconductor module of Example 1;

FIG. 4 is a graph illustrating the forward current-voltage characteristic of the power semiconductor module of Example 1;

FIG. 5 is a diagram illustrating an equivalent circuit of the power semiconductor module of Example 2;

FIG. 6 is a diagram illustrating a turn-off waveform of a wide bandgap semiconductor switching device and a Si-IGBT;

FIG. 7 is a diagram illustrating a turn-off waveform of a power semiconductor module of Example 3;

FIG. 8 is a diagram illustrating a turn-on waveform of a wide bandgap semiconductor switching device and a Si-IGBT;

FIG. 9 is a diagram illustrating a turn-on waveform of a power semiconductor module of Example 4; and

FIG. 10 is a diagram illustrating an equivalent circuit of a gate driving circuit of a power semiconductor module of Example 5.

### DETAILED DESCRIPTION

The present embodiment provides a power semiconductor module which can reduce power loss even when the chip area of the SiC-MOSFET is smaller than that of the Si-IGBT of the related art and suppress an oscillation at the time of switching so as to prevent and generation of an excessive voltage or a noise.

A power semiconductor module according to an embodiment includes a unipolar type switching device using a wide bandgap semiconductor (wide bandgap semiconductor switching device) and an insulated gate bipolar transistor using a silicon semiconductor (Si-IGBT) and they are connected in parallel. In addition, a chip area of the wide bandgap semiconductor switching device is smaller than that of the Si-IGBT, and an on-voltage of the power semiconductor module is approximately equal to an on-voltage of the wide bandgap semiconductor switching device having a chip area equal to that of the Si-IGBT.

in the Si-IGBT of the related art, an on-voltage can be lowered by injecting minority carriers into a drift layer (bipolar operation). However, it is necessary to discharge minority carriers accumulated in the device at the time of the turn-off operation so that the switching time is long, and the switching loss is significant.

Meanwhile, in the wide bandgap semiconductor switching device, the on-resistance per unit area can be lowered in comparison with a Si-IGBT of the related art, so that the on-state loss (conduction loss) can be reduced.

Furthermore, since minority carriers are not accumulated in the wide bandgap semiconductor switching device, a high-speed switching and a low-loss switching operation can be performed in comparison with the Si-IGBT.

Currently, the MOSFET or the JFET using SiC as the wide bandgap semiconductor switching device is commercially available in the art. The present embodiment will be described below as an example the case, using the SiC-MOSFET.

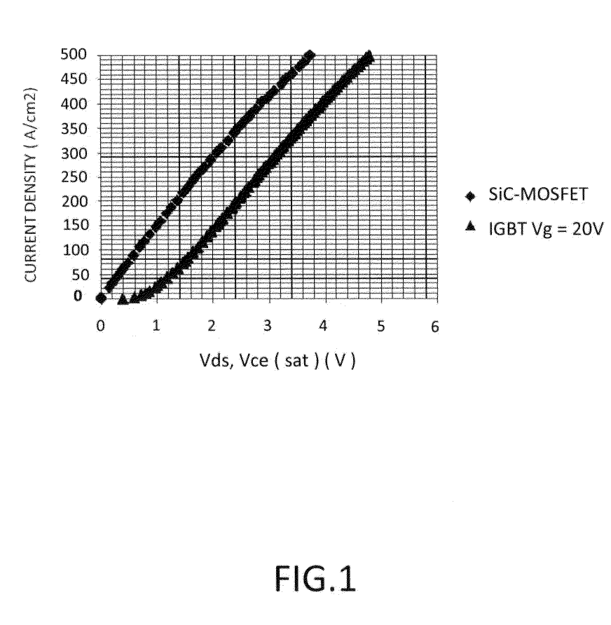

FIG. 1 illustrates a comparison example of the forward current-voltage characteristic per unit area at a device temperature of 150° C. between the SiC-MOSFET and the Si-IGBT.

Referring to FIG. 1, the on-voltage of the SiC-MOSFET is lower than that of the Si-IGBT at the same current density. Therefore, it is recognized that the conduction loss of the SiC-MOSFET is lower than that of the Si-IGBT.

Comparing a current price per unit area between the wide bandgap semiconductor switching device and the Si-IGBT, the price of the wide bandgap semiconductor switching device is higher several times. Therefore, under the same rated current, it is preferable that the wide bandgap semiconductor switching device have a chip area smaller than that of the Si-IGBT from the viewpoint of the cost.

In the current market status, a development technology of the wide bandgap semiconductor switching device is not advanced compared to the Si-IGBT. In addition, assuming that the wide bandgap semiconductor switching devices are manufactured in the same chip area as that of the Si-IGBT, a product yield of the wide bandgap semiconductor switching devices is significantly lower than that of the Si-IGBT. Therefore, it is difficult to manufacture the same number of switching devices with the same chip area as that of the Si-IGBT.

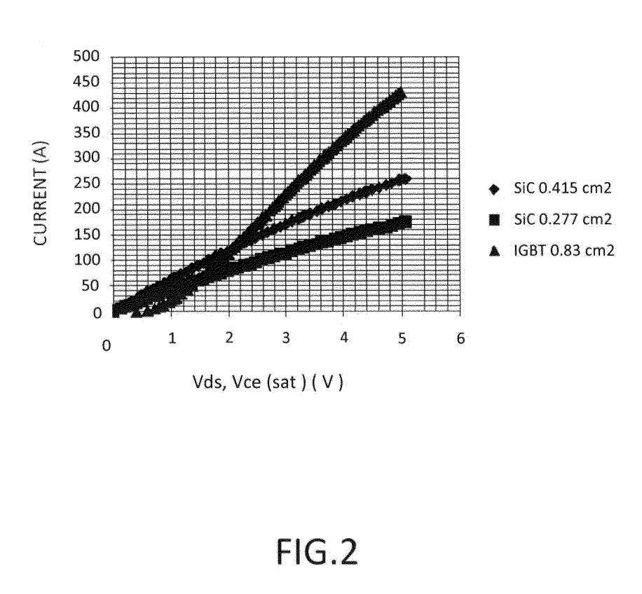

FIG. 2 illustrates a comparison example of the forward current-voltage characteristic when a ratio of the chip area between the SiC-MOSFET and the Si-IGBT is set to ½ or ⅓ in a case where the chip area of the Si-IGBT is set to 1.

Referring to FIG. 2, if the chip area of the SiC-MOSFET is smaller than that of the Si-IGBT, the on-voltage of the SiC-MOSFET increases to be higher than that of the Si-IGBT in the high-current area. This means that if the chip area of the SiC-MOSFET is set to be smaller than that of the Si-IGBT to reduce the cost the on-voltage of the SiC-MOSFET is higher than that of the Si-IGBT at the rated current. Therefore, the conduction loss increases, and an advantage of using the SiC-MOSFET is reduced.

In addition, since the SiC-MOSFET performs a high-speed switching operation, the voltage-current waveform oscillates during the switching, and this oscillation becomes a noise source. Furthermore, an excessive voltage is also generated along with the oscillation, and the switching device may be malfunctioned.

The embodiment has been made to address such problems and provide a power semiconductor module which can reduce power loss even with the chip area of the SiC-MOSFET smaller than that of the Si-IGBT of the related art and suppress the oscillation during the switching so as to prevent the occurrence of a noise or an excessive voltage.

According to a first embodiment, there is provided a power semiconductor module including a unipolar type switching device using a wide bandgap semiconductor (wide bandgap semiconductor switching device) and an insulated gate bipolar transistor using a silicon semiconductor (Si-IGBT), and they are connected in parallel. The chip area of the wide bandgap semiconductor switching device is smaller than that of the Si-IGBT, and an on-voltage of the power semiconductor module at the rated current is approximately equal to an on-voltage of the wide bandgap semiconductor switching device having a chip area equal to that of the Si-IGBT at the rated current.

It is preferable that an area ratio between the wide bandgap semiconductor switching device and the Si-IGBT to be approximately set to 1:2 to 1:4. By setting such an area ratio, it is possible to set the on-voltage of the power semiconductor module to be approximately equal to the on-voltage of the wide bandgap semiconductor switching device having the same chip area as that of the Si-IGBT.

According to a second embodiment, the power semiconductor module includes a diode inversely connected to the power semiconductor module in parallel.

According to a third embodiment, there is provided a method of driving a power semiconductor module, in which the Si-IGBT is turned on first and the wide bandgap semiconductor switching device is turned on after a collector-emitter voltage of the Si-IGBT reaches an on-voltage.

According to a fourth embodiment, there is provided a method of driving a power semiconductor module, in which the Si-IGBT is turned on first and the wide bandgap semiconductor switching device is turned off after a current flowing through the Si-IGBT is dissipated.

In each configuration described above, it is possible to realize a power semiconductor module which has low power loss and suppresses the occurrence of a noise and an excessive voltage.

### Example 1

Hereinafter, Examples of embodiments will be described with reference to the accompanying drawings. First, a power semiconductor module according to Example 1 will be described.

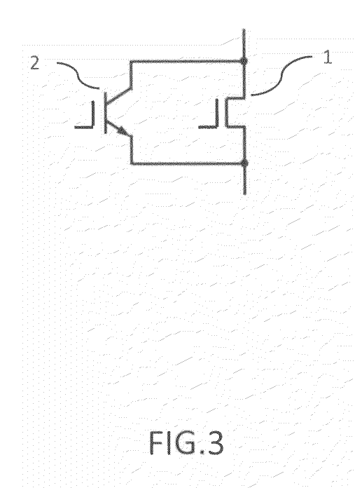

FIG. 3 illustrates a diagram of an equivalent circuit of the power semiconductor module according to Example 1. The power semiconductor module includes a wide bandgap semiconductor switching device 1 and a Si-IGBT 2 connected in parallel with the wide bandgap semiconductor switching device 1. That is, the drain terminal of the wide bandgap semiconductor switching device 1 is connected to the collector terminal of the Si-IGBT 2, and the source terminal of the wide bandgap semiconductor switching device 1 is connected to the emitter terminal of the Si-IGBT 2. In the power semiconductor module, the used wide bandgap semiconductor switching device 1 has a chip area smaller than that of the Si-IGBT 2.

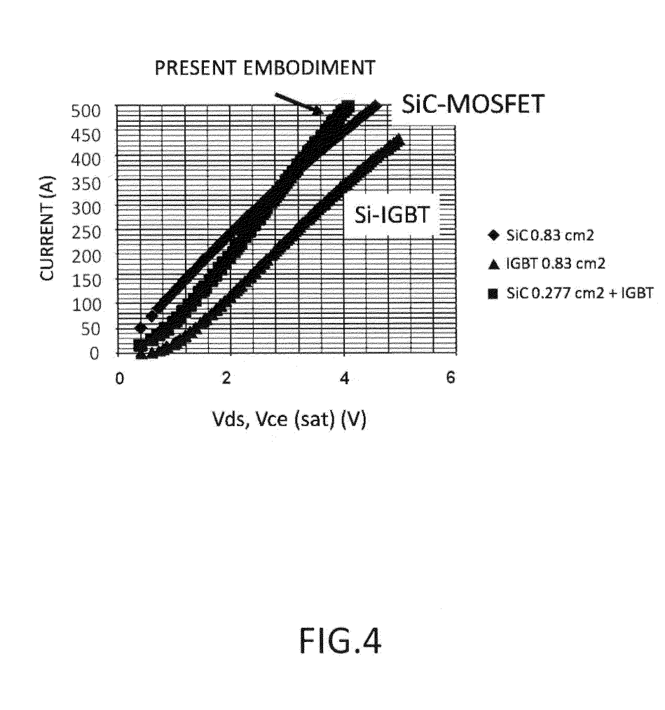

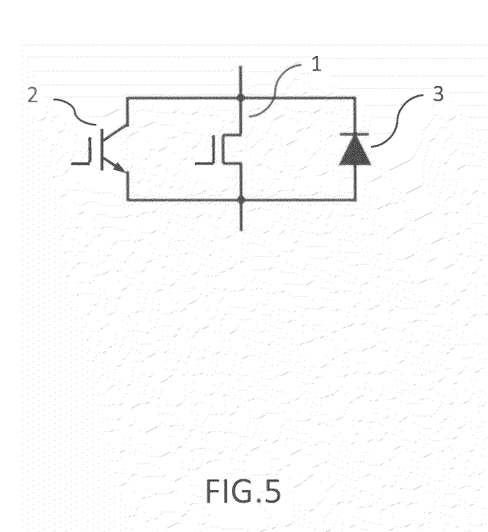

FIG. 4 illustrates a measurement result of the forward current-voltage characteristic of the power semiconductor module according to Example 1 and shows a case where the SiC-MOSFET is used as the wide bandgap semiconductor switching device. In the current-voltage characteristic 1 of the power semiconductor module of Example 1, the chip area of the SiC-MOSFET is ⅓ times that of the Si-IGBT. For comparison purposes, description will be made for the current-voltage characteristic 2 of a single Si-IGBT and the current-voltage characteristic 3 of the SiC-MOSFET having the same chip area as that of the Si-IGBT. Referring to FIG. 4, it is recognized that the current-voltage characteristic 1 of the power semiconductor module of Example 1 is similar to the current-voltage characteristic 2 of the SiC-MOSFET, and the characteristic of the SiC-MOSFET having a large chip area (in this example, triple area) can be realized using the SiC-MOSFET having a small chip area.

### Example 2

Example 2 relates to a power semiconductor module which includes a diode connected to the power semiconductor module of Example 1 in parallel. An equivalent circuit of the power semiconductor module of Example 2 is illustrated in FIG. 5. The configurations of the wide bandgap semiconductor switching device 1 and the Si-IGBT 2 are similar to those of Example 1. The drain terminal of the wide bandgap semiconductor switching device 1 and the collector terminal of the Si-IGBT 2 are connected to the cathode terminal of the diode 3. The source terminal of the wide bandgap semiconductor switching device 1 and the emitter terminal of the Si-IGBT 2 are connected to the anode terminal of the diode 3.

In a case where the power semiconductor module according to the present embodiment is applied to an inverter circuit or a chopper circuit, a free-wheeling diode is necessary to flow a free-wheeling current in parallel with the switching device. As a result, in a case where a diode is not internally provided in the wide bandgap semiconductor switching device 2, and a case where it is not desired to flow the current through the internal diode, it is possible to flow the free-wheeling current through the diode 3.

### Example 3

Hereinafter, a method of turning off the power semiconductor module of Example 1 will be described.

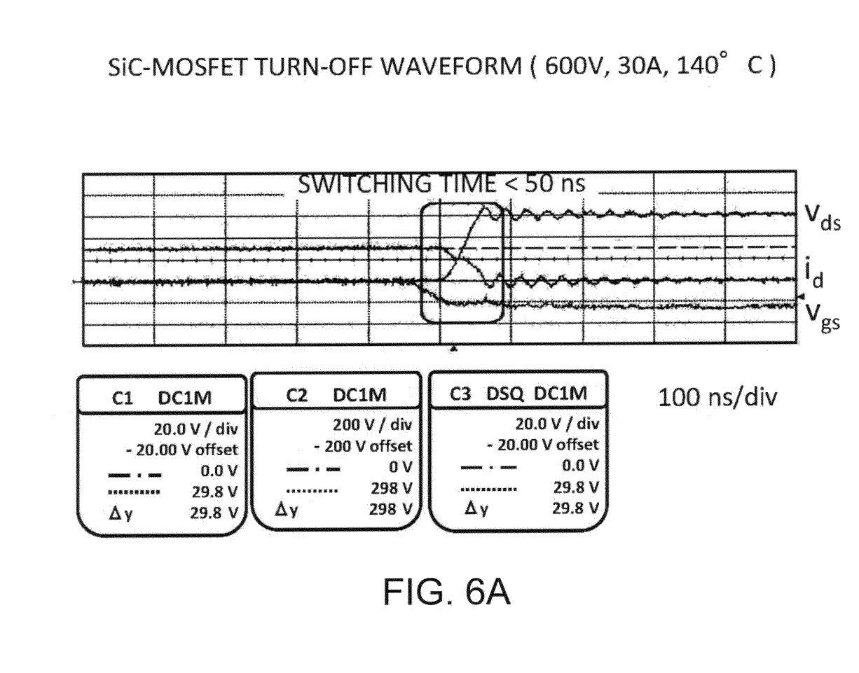

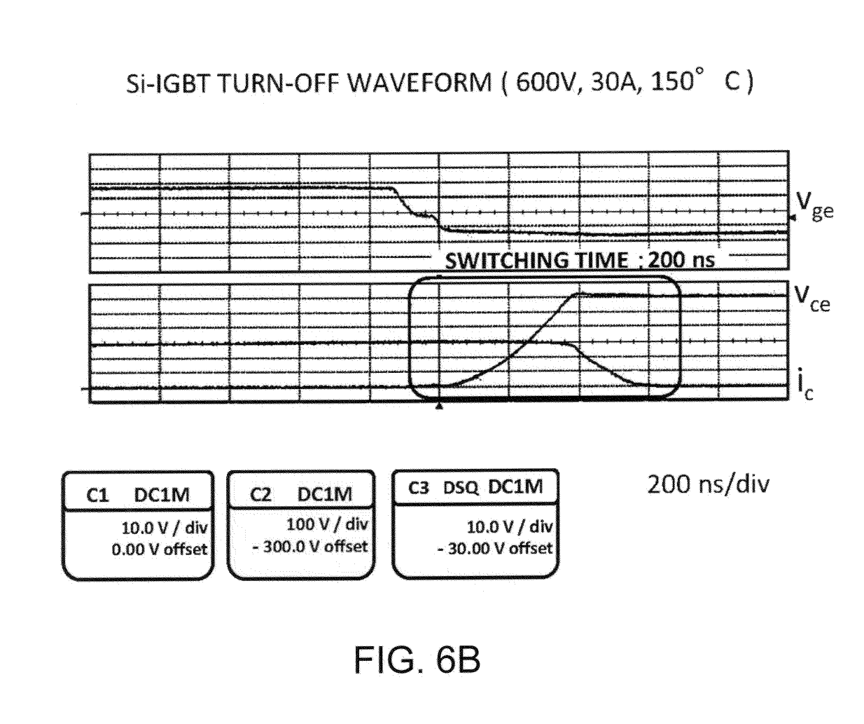

FIG. 6 illustrates a voltage and current waveforms when the wide bandgap semiconductor switching device and the Si-IGBT are turned off. As apparent from FIG. 6, the turn-off time of the Si-IGBT is longer than the turn-off time of the wide bandgap semiconductor switching device. Therefore, it is problematic that the turn-off loss is large.

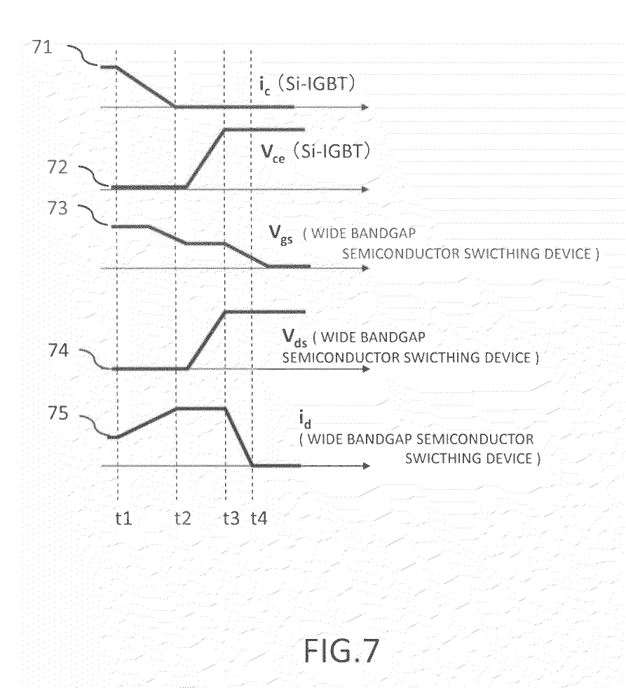

FIG. 7 illustrates a collector current waveform 71 of the Si-IGBT, a collector-emitter waveform 72, a gate-source voltage waveform 73 of the wide bandgap semiconductor switching device, a drain-source voltage waveform 74, and a drain current waveform 75 when the power semiconductor module of Example 3 is turned off.

In the turn-off method of the present example, first, a turn-off signal is input to the gate of the Si-IGBT, and the Si-IGBT is first turned off. At this time, the wide bandgap semiconductor switching device is in a turn-on state. After the collector current 71 of the Si-IGBT becomes zero (after time t2), the wide bandgap semiconductor switching device is turned off at the timing when the drain-source voltage 74 of the wide bandgap semiconductor switching device starts to rise. Since the wide bandgap semiconductor switching device and the Si-IGBT are connected in parallel, the collector-emitter voltage 72 of the Si-IGBT has a waveform similar to that of the drain-source voltage 74 of the wide bandgap semiconductor switching device. In addition, since the collector current 71 of the Si-IGBT decreases during the period of time t1 to t2, the drain current 75 of the wide bandgap semiconductor switching device increases. The overall current flowing through the power semiconductor module for the period of time t2 to t3 also flows through the wide bandgap semiconductor switching device. As the gate-source voltage 73 of the wide bandgap semiconductor switching device reaches a threshold voltage (t4), the drain current 75 of the wide bandgap semiconductor switching device becomes zero, and the turn-off operation is terminated.

In the method of turning off the power semiconductor module according to Example 3, it is possible to avoid a problem that the turn-off loss of the Si-IGBT is significant. Since the turn-off loss is defined by the characteristic of the wide bandgap semiconductor switching device, the turn-off loss can be reduced.

### Example 4

Next, a method of turning on the power semiconductor module according to Example 4 will be described.

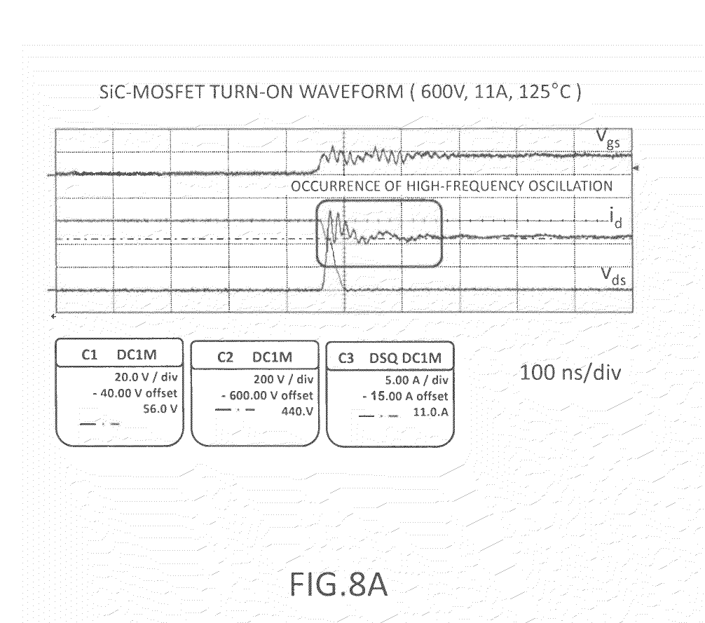

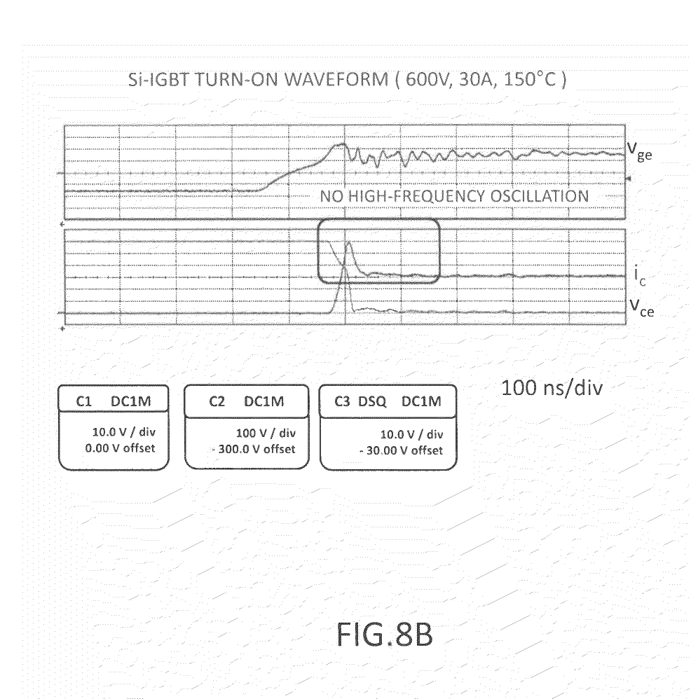

FIG. 8 illustrates a voltage and current waveforms when the wide bandgap semiconductor switching device and the Si-IGBT are turned on. As apparent from FIG. 8, a high-frequency oscillation occurs in the turn-on current waveform of the wide bandgap semiconductor switching device. It is problematic that this oscillation acts as a noise source.

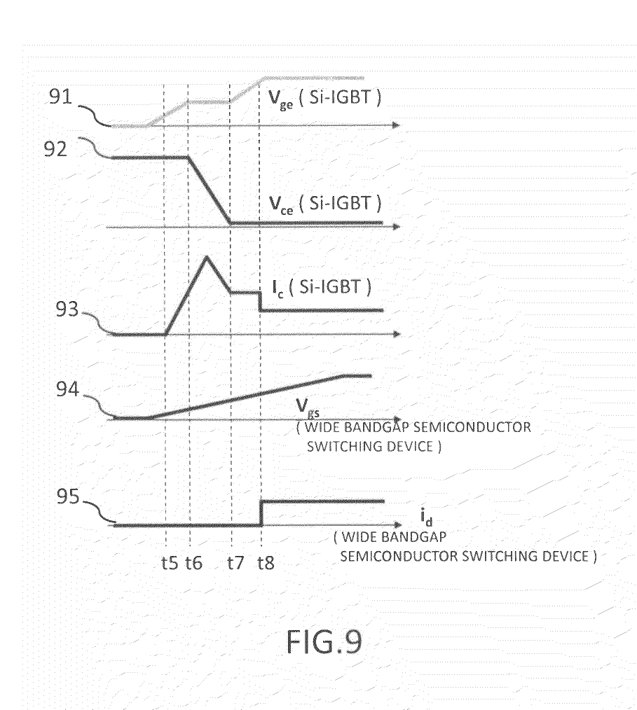

FIG. 9 illustrates a gate-emitter voltage 91 of the Si-IGBT, a collector-emitter voltage 92, a collector current waveform 93, a gate-source voltage waveform 94 of the wide bandgap semiconductor switching device, and a drain current 95 when the power semiconductor module of Example 4 is turned on. In the turn-on method according to the present invention, first, the turn-on signal is input to the gate of the Si-IGBT to turn on the Si-IGBT first. At this time, the wide bandgap semiconductor switching device is in a turn-off state. After the collector-emitter voltage 92 of the Si-IGBT reaches the on-voltage (after time t7), the wide bandgap semiconductor switching device is turned on such that the gate-source voltage 94 of the wide bandgap semiconductor switching device reaches a threshold value. Since the wide bandgap semiconductor switching device and the Si-IGBT are connected in parallel, the drain-source voltage (not shown) of the wide bandgap semiconductor switching device has the waveform similar to the collector-emitter voltage 92 of the Si-IGBT. As the gate-source voltage 94 of the wide bandgap semiconductor switching device reaches a threshold voltage (t8), current flows through the wide bandgap semiconductor switching device so that the turn-on operation is terminated. In addition, since only the Si-IGBT is in a turn-on state during the period of time t5 to t8, the overall current flowing through the power semiconductor module flows through the Si-IGBT.

As described above, in the method of turning on the power semiconductor module according to Example 4, it is possible to remove the effect of the high-frequency oscillation (noise source), which is problematic in the unipolar device, by turning on the Si-IGBT first. In this manner, it is possible to avoid a problem of the oscillation in the waveform of the wide bandgap semiconductor switching device. Since the turn-on waveform is defined by the characteristic of the Si-IGBT, it is possible to suppress the occurrence of the oscillation. In addition, since the turn-on time of the Si-IGBT is nearly the same as the turn-on time of the SiC-MOSFET, the turn-on loss is not increased.

### Example 5

Next, a gate driving circuit of the power semiconductor module according to Example 5 will be described.

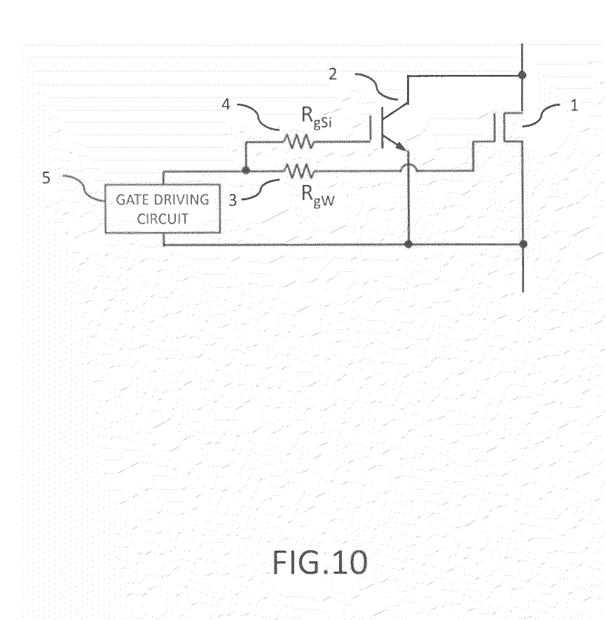

FIG. 10 illustrates an equivalent circuit of the gate driving circuit of the power semiconductor module according to Example 5. The gate terminal of the wide bandgap semiconductor switching device 1 is connected to the gate driving circuit 5 through the gate resistance RgW 3, and the gate terminal of the Si-IGBT 2 is connected to the gate driving circuit 5 through the gate resistance RgSi 4.

It is known that the switching time of the switching device is a function of the product between the gate input capacitance Ciss, the gate free-wheeling capacitance Crss, and the gate resistance.

In the gate driving circuit of the power semiconductor module according to Example 5, the values RgSi, RgW, Ciss, and Crss are selected to satisfy the following relation:

RgSi×Ciss(Si-IGBT)<RgW×Ciss(wide bandgap semiconductor switching device) (1), and

RgSi×Crss(Si-IGBT)<RgW×Crss(wide bandgap semiconductor switching device) (2).

As a result, the Si-IGBT can be turned on first in the turn-on operation, and the Si-IGBT can be turned off first in the turn-off operation. In addition, both the Si-IGBT and the wide bandgap semiconductor switching device can be driven using a single gate driving circuit.

Although some embodiments have been described hereinbefore, those embodiments are just exemplary and are not intended to limit the scope of the invention. Such embodiments may be embodied in various other forms, and various omissions, substitutions, or changes may be possible without departing from the spirit and scope of the invention. Such embodiments and modifications are construed to encompass the scope of the invention and equivalents thereof if they are similarly included in the scope or subject matter of the invention.

What is claimed is:

1. A power semiconductor module comprising:
a unipolar type switching device using a wide bandgap semiconductor (wide bandgap semiconductor switching device); and
an insulated gate bipolar transistor using a silicon semiconductor (Si-IGBT) connected in parallel with the wide bandgap semiconductor switching device,
wherein a chip area of the wide bandgap semiconductor switching device is smaller than that of the Si-IGBT, and
a turn-on voltage of the power semiconductor module is approximately equal to a turn-on voltage of the wide bandgap semiconductor switching device having a chip area equal to that of the Si-IGBT.

2. The power semiconductor module according to claim 1,
wherein an area ratio between the wide bandgap semiconductor switching device and the Si-IGBT is set to 1:2 to 1:4.

3. The power semiconductor module according to claim 1,
wherein a diode is inversely connected to the power semiconductor module in parallel.

4. The power semiconductor module according to claim 1,
wherein the wide bandgap semiconductor switching device is made of at least a material selected from a group including silicon carbide (SiC), gallium nitride (GaN), or diamond.

5. The power semiconductor module according to claim 1,
wherein the wide bandgap semiconductor switching device and the Si-IGBT are driven by an individual gate driving circuit.

6. The power semiconductor module according to claim 1,
wherein the wide bandgap semiconductor switching device and the Si-IGBT are driven by the same gate driving circuit.

7. The power semiconductor module according to claim 1,
wherein the wide bandgap semiconductor switching device, the Si-IGBT, and the gate driving circuit are enclosed in the same package.

8. The power semiconductor module according to claim 1,
wherein the wide bandgap semiconductor switching device, the Si-IGBT, the diode, and the gate driving circuit are enclosed in the same package.

9. A method of driving power semiconductor module that includes a unipolar type switching device using a wide bandgap semiconductor (wide bandgap semiconductor switching device) and an insulated gate bipolar transistor using a silicon semiconductor (Si-IGBT) connected in parallel, in which a chip area of the wide bandgap semiconductor switching device is smaller than a chip area of the Si-IGBT and a turn-on voltage of the power semiconductor module is approximately equal to a turn-on voltage of the wide bandgap semiconductor switching device having a chip area approximately equal to that of the Si-IGBT, and the method comprising:
turning on the Si-IGBT first; and
turning on the wide bandgap semiconductor switching device after a collector-emitter voltage of the Si-IGBT reaches an on-voltage.

10. A method of driving a power semiconductor module that includes a unipolar type switching device using a wide bandgap semiconductor (wide bandgap semiconductor switching device) and an insulated gate bipolar transistor using a silicon semiconductor (Si-IGBT) connected in parallel, in which a chip area of the wide bandgap semiconductor switching device is smaller than a chip area of the Si-IGBT and an on-voltage of the power semiconductor module is approximately equal to an on-voltage of the wide bandgap semiconductor switching device having a chip area approximately equal to that of the Si-IGBT, the method comprising:
turning off the Si-IGBT first; and
turning off the wide bandgap semiconductor switching device after a current of the Si-IGBT flowing through the Si-IGBT is dissipated.
